(19) United States
(12) Patent Application Publication
(10) Pub. No.: US 2026/0271475 A1
(43) Pub. Date: Sep. 10, 2026

(54) THIN FILM PHOTODETECTOR APPLIED WITH NEW MULTILAYER STRUCTURE AND METHOD FOR MANUFACTURING SAME

(71) Applicant: CHUNG-ANG UNIVERSITY INDUSTRY ACADEMIC COOPERATION FOUNDATION, Seoul (KR)

(72) Inventors: Dong Hwan WANG, Seoul (KR); Woong Sik JANG, Seoul (KR)

(21) Appl. No.: 19/263,116

(22) Filed: Jul. 8, 2025

(30) Foreign Application Priority Data
Mar. 6, 2025 (KR) 10-2025-0028933

(51) Int. Cl. H10K 30/30; H10K 71/18; H10K 85/20

(52) U.S. Cl. CPC H10K 30/353; H10K 71/18; H10K 85/215

(57) ABSTRACT

According to an embodiment, a photodetector including a novel planar heterojunction structure is provided, which facilitates rapid charge transport at a donor-acceptor interface and blocks charge injection from a contact region having low barrier energy for each electrode, thereby improving the photocurrent performance of a device and reducing dark current.

### CROSS-REFERENCE TO RELATED APPLICATION

The present application claims priority to Korean Patent Application No. 10-2025-0028933, filed Mar. 6, 2025, the entire contents of which are incorporated here for all purposes by this reference.

### BACKGROUND

The disclosure relates to a photodetector, and more particularly, to a thin film photodetector including a novel multilayer structure.

Organic photodetectors have been studied extensively due to their advantages, such as the excellent color separation capability of organic materials as a photoreactive layer and their flexible characteristics. In particular, many studies have been reported on increasing the performance of organic photodetectors by introducing an effective photosensitive layer. In addition, studies have been reported on introducing a heterojunction structure in which an electron donor and an electron acceptor are mixed in the photosensitive layer as a structure to improve photoreactivity.

However, previously reported studies have been limited to heterojunction structures. The existing heterojunction structure has problems such as a slow reaction rate due to random charge transfer paths, and a contact between the electron donor and the lower electrode, which may form a relatively low injection barrier, is formed, making it vulnerable to noise current. To solve this problem, there have been attempts to form an electron acceptor material in the lower layer, but since the lower layer penetration is inevitable due to the limitations of the solution process, there was a problem that forming a continuous structure was impossible.

### RELATED ART DOCUMENT

### Patent Document

(Patent Document 1) US Publication No. US 2024/0049588 A1

### SUMMARY

The disclosure provides a thin-film organic photodetector having a novel multilayer structure that can effectively separate charges formed by an optical signal and suppress reverse charge flow due to injected charges through a transfer printing process.

The aspect of the disclosure is not limited to that mentioned above, and other aspects not mentioned will be clearly understood by those skilled in the art from the description below.

An embodiment of the disclosure provides a photodetector.

A photodetector according to an embodiment of the disclosure includes: a first electrode; a blocking layer formed on the first electrode; a photosensitive layer formed on the blocking layer; and a second electrode formed on the photosensitive layer, wherein the photosensitive layer includes a bulk heterojunction layer in which a second electron acceptor material and a first electron donor material are mixed on a thin film layer including a first electron acceptor material.

In an embodiment of the disclosure, the polymer layer may be formed through a transfer printing process.

In an embodiment of the disclosure, the first electron acceptor material may be PC₇₁BM.

In an embodiment of the disclosure, the first electron donor material may be one of PM6, PBDTTTEFT, PCDTBT, and P3HT, and the second electron acceptor material may be one of BTP-4F, BTP-4F-12, BTP-eC9, ITIC, IDTBR, and IEICO-4F.

In an embodiment of the disclosure, the blocking layer may be a hole blocking layer.

In an embodiment of the disclosure, the blocking layer may include ZnO.

In an embodiment of the disclosure, the second electron acceptor material and the first electron donor material of the bulk heterojunction layer may have a mass ratio of 1:0.5 to 2.

Another embodiment of the disclosure provides a method for manufacturing a photodetector.

A method for manufacturing a photodetector according to an embodiment of the disclosure includes: applying a blocking layer composition on a first electrode; coating a thin film layer including a first electron acceptor material on the first electrode to which the blocking layer composition is applied; forming a bulk heterojunction layer in which a second electron acceptor material and a first electron donor material are mixed through a transfer printing process on the thin film layer; and forming a second electrode on the bulk heterojunction layer.

In an embodiment of the disclosure, the transfer printing process may be performed at a speed of 0.1 cm·s⁻¹ to 0.3 cm·s⁻¹.

In an embodiment of the disclosure, the forming of the bulk heterojunction layer may be performed in a temperature range of 373K to 403K.

According to an embodiment of the disclosure, a photodetector including a planar heterojunction structure of an A/BHJ structure is provided to facilitate rapid charge transport at a donor-acceptor interface and block charge injection from a contact region having low barrier energy for each electrode, thereby improving the photocurrent performance of the device and reducing dark current.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram showing a photodetector according to an embodiment of the disclosure;

FIG. 2 is a diagram showing the relationship between energy release rate and temperature in a photodetector manufacturing method according to an embodiment of the disclosure;

FIG. 3 is a diagram showing energy release rate according to speed under various interfaces;

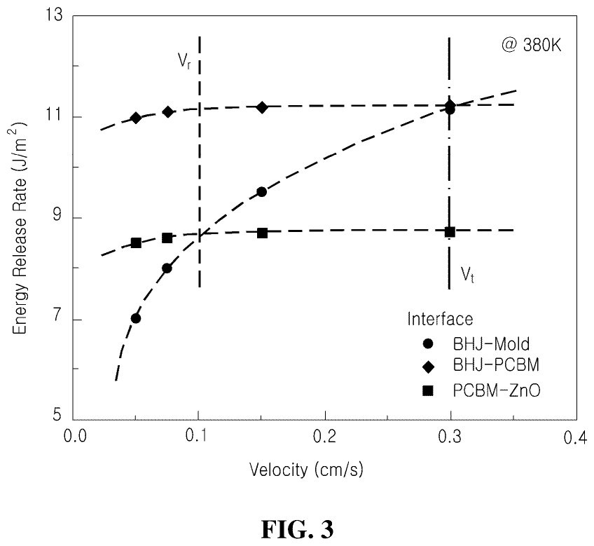

FIG. 4 is a diagram showing energy release rate change at an interface according to temperature change in a photodetector manufacturing method according to an embodiment of the disclosure;

FIG. 5 is a cross-sectional image of a photodetector having an A/BHJ structure according to an embodiment of the disclosure;

FIG. 6 is a diagram depicting charge carrier movement in a photodetector according to an embodiment of the disclosure;

FIG. 7A is a diagram showing UPS results from an ITO/ZnO surface;

FIG. 7B is a diagram showing UPS results from an ITO/ZnO/PC₇₁BM surface;

FIG. 7C is a diagram showing UPS results from an ITO/ZnO/PC₇₁BM and a spin-coated BHJ layer surface;

FIG. 7D is a diagram showing the UPS results from the surface of an ITO/ZnO/PC₇₁BM and a transfer-printed coated BHJ layer;

FIG. 7E is an energy level diagram for an ITO/ZnO/PC₇₁BM structure;

FIG. 7F is an energy level diagram for a photodetector including a spin-coated A/BHJ structure;

FIG. 7G is an energy level diagram for a photodetector including a transfer-printed A/BHJ structure;

FIG. 8A is a diagram showing a J-V curve under light conditions of a photodetector according to an embodiment of the disclosure;

FIG. 8B is a diagram showing a J-V curve under dark conditions of a photodetector according to an embodiment of the disclosure;

FIG. 8C is a diagram showing an EQE spectrum of a photodetector according to an embodiment of the disclosure;

FIG. 8D is a diagram showing the response results under self-generation operation of each fabricated element;

FIG. 8E is a diagram showing a noise spectral density of a photodetector according to an embodiment of the disclosure;

FIG. 8F is a diagram showing the specific detectivity of each fabricated element;

FIG. 9A is a TRPL diagram of a photodetector according to an embodiment of the disclosure;

FIG. 9B is a J-V plot of a photodetector according to an embodiment of the disclosure;

FIG. 9C is a SCLC diagram of a photodetector according to an embodiment of the disclosure;

FIG. 9D is a diagram showing the results of trap-assisted tunneling analysis of a photodetector according to an embodiment of the disclosure;

FIG. 9E is an IMPS spectrum of a photodetector according to an embodiment of the disclosure;

FIG. 9F is an IMPS spectrum of a photodetector according to an embodiment of the disclosure;

FIG. 9G is an IMVS spectrum of a photodetector according to an embodiment of the disclosure;

FIG. 9H is an IMVS spectrum of a photodetector according to an embodiment of the disclosure;

FIG. 10A is a diagram showing transient photocurrent values based on light stimulation of a photodetector according to an embodiment of the disclosure;

FIG. 10B is a diagram showing cutoff frequency analysis of a photodetector according to an embodiment of the disclosure;

FIG. 10C is a diagram showing frequency-dependent photocurrent at 100 kHz of a photodetector according to an embodiment of the disclosure;

FIG. 10D is a diagram showing frequency-dependent photocurrent at 400 kHz of a photodetector according to an embodiment of the disclosure;

FIG. 10E is a diagram showing the SNR results at 100 kHz of a photodetector according to an embodiment of the disclosure;

FIG. 10F is a diagram showing the SNR results at 400 kHz of a photodetector according to an embodiment of the disclosure;

FIG. 11A is a diagram showing a wireless data communication system using a light pulse including a photodetector according to an embodiment of the disclosure;

FIG. 11B is a diagram showing an example of wireless data communication using a photodetector according to an embodiment of the disclosure;

FIG. 11C is a diagram showing an example of wireless data communication using a photodetector according to an embodiment of the disclosure;

FIG. 11D is a diagram showing the rapid detection performance of a wireless data system including a photodetector according to an embodiment of the disclosure; and

FIG. 11E is a diagram showing the rapid detection performance of a wireless data system including a photodetector according to an embodiment of the disclosure.

### DETAILED DESCRIPTION

Hereinafter, the disclosure will be described with reference to the accompanying drawings. However, the disclosure may be implemented in various different forms and therefore is not limited to the embodiments described herein. In addition, in order to clearly describe the disclosure in the drawings, parts that are not related to the description are omitted, and similar parts are given similar drawing reference numerals throughout the specification.

In the entire specification, when a part is said to be “connected (linked, contacted, coupled)” to another part, this includes not only the case where it is “directly connected” but also the case where it is “indirectly connected” with another member in between. In addition, when a part such as a layer, film, region, or plate is said to be “on” another part, this includes not only the case where it is “directly on” another part, but also the case where there is another part in between.

The terms used in this specification are used only to describe specific embodiments and are not intended to limit the disclosure. The singular expression includes the plural expression unless the context clearly indicates otherwise. In this specification, the terms “include” or “have” are intended to specify the presence of a feature, number, step, operation, component, part, or combination thereof described in the specification, but should be understood as not excluding in advance the possibility of the presence or addition of one or more other features, numbers, steps, operations, components, parts, or combinations thereof.

Hereinafter, embodiments of the disclosure will be described in detail with reference to the accompanying drawings.

### A Photodetector According to an Embodiment of the Disclosure Will be Described.

A photodetector according to an embodiment of the disclosure includes: a first electrode; a blocking layer formed on the first electrode; a photosensitive layer formed on the blocking layer; and a second electrode formed on the photosensitive layer,
wherein the photosensitive layer includes a bulk heterojunction layer in which a second electron acceptor material and a first electron donor material are mixed on a thin film layer including a first electron acceptor material.

In an embodiment of the disclosure, the first electrode may be an anode, and the second electrode may be a cathode.

The first electrode or the second electrode may each include fluorine-containing tin oxide, indium-containing tin oxide, aluminum-containing zinc oxide, indium-containing zinc oxide, or a mixture thereof, or gold (Au), silver (Ag), platinum (Pt), palladium (Pd), copper (Cu), aluminum (Al), carbon (C), cobalt sulfide (CoS), copper sulfide (CuS), nickel oxide (NiO), or a mixture thereof, but is not particularly limited to the compounds. As a more preferred embodiment, the first electrode may include indium tin oxide (ITO), and the second electrode may include aluminum.

The first electrode and the second electrode are formed facing each other.

A substrate may be additionally arranged below the first electrode or above the second electrode. A glass substrate or a plastic substrate having excellent mechanical strength, thermal stability, transparency, surface smoothness, ease of handling, and waterproofing may be used as the substrate, but this is not limited thereto. A composition for the first electrode or the second electrode may be formed on the substrate using a deposition method or a sputtering method, etc.

In an embodiment of the disclosure, the blocking layer is formed between the first electrode and the second electrode. The blocking layer may be a hole blocking layer (HBL).

The hole blocking layer may effectively block holes moving to the anode without blocking the transmission of electrons being transmitted. For example, the hole blocking layer may be ~, but is not particularly limited to the above-described examples. In a more preferred embodiment, the hole blocking layer may include zinc oxide (ZnO).

In an embodiment of the disclosure, the photosensitive layer is a key part of the disclosure. In previous studies, a bulk heterojunction structure composed of an electron donor material and an electron acceptor material was proposed as a photosensitive layer material to improve the photoresponsiveness of the photosensitive layer; however, this heterojunction structure had problems such as slow reaction speed due to random charge transfer paths and vulnerability to noise current.

Therefore, in the disclosure, an electron acceptor material was formed under the heterojunction structure to provide a photosensitive layer including an acceptor/bulk heterojunction structure (hereinafter, A/BHJ structure) to solve the above-mentioned problems.

However, in the case of the existing solution process, continuous structure formation was impossible because the penetration of the lower layer was inevitable, and even if the previously reported transfer process was introduced, the interfacial adhesion between the hole blocking layer (zinc oxide, ZnO) formed under the photosensitive layer and the electron acceptor material was low, making its application difficult.

Accordingly, the inventors of the disclosure adopted the transfer printing process method described below to form a bulk heterojunction structure on the thin film layer, and were able to form a stable interface through this. In the transfer printing process, the bulk heterojunction layer after drying is transferred from the medium to the thin film layer by physically contacting the medium and the target thin film layer, and the limitations of the existing solution process can be solved.

Of course, in order to stably form the above-mentioned bulk heterojunction layer, it is important to appropriately control the adhesive force at the interface between the medium and the target thin film layer to be transferred, and it is necessary to appropriately control the peeling speed and temperature during the transfer printing process.

At this time, the first electron acceptor material of the thin film layer corresponding to the lower layer of the photosensitive layer may be, for example, a material having a highest occupied molecular orbital of 5.5 eV to 7.0 eV and a band gap energy of 1.5 eV to 3 eV or more, and specific examples thereof may include ICBA (Indene-C60 bisadduct), PC₆₁BM([6,6]-Phenyl-C61-butyric acid methyl ester), PC₇₁BM([6,6]-Phenyl-C71-butyric acid methyl ester), etc., but are not limited thereto. As a more preferred embodiment, the first electron acceptor material may be PC₇₁BM. The PC₇₁BM is an acceptor having a high band gap energy and a deep highest occupied molecular orbital (HOMO) level, and may contribute to the stable formation of the A/BHJ structure.

The bulk heterojunction layer, which corresponds to the upper layer of the photosensitive layer, has a form in which the first electron donor material and the second electron acceptor material are bonded in bulk.

At this time, the first electron donor material may include, for example, poly[2,6′-4,8-di(5-ethylhexylthienyl)benzo[1,2-b:4,5-b′]dithiophene-alt-4,7-(2,1,3-benzothiadiazole)] (PM6), poly[4,8-bis(5-(2-ethylhexyl)thiophen-2-yl)benzo[1,2-b:4,5-b′]dithiophene-alt-ethylhexyl-4H-thieno[3,4-c]pyrrole-4,6(5H)-dione] (PBDTTTEFT), poly[N-9′-heptadecanyl-2,7-carbazole-alt-5,5-(4′,7′-di-2-thienyl-2′,1′,3′-benzothiadiazole)] (PCDTBT), and poly(3-hexylthiophene) (P3HT), but is not limited thereto. As a more preferred embodiment, the first electron donor material may be PM6 (PBDB-T-2F).

At this time, the second electron acceptor material may include, for example, 2,2′-((2Z,2′Z)-((12,13-bis(2-ethylhexyl)-3,9-diundecyl-12,13-dihydro-[1,2,5]thiadiazolo[3,4-e]thieno[2,′″:5′,6]pyrazino[2,3-g]thieno[3,′″:4′,5]thieno[2,3-b]indole-2,10-diyl)bis(methanylylidene))bis(5,6-difluoro-3-oxo-2,3-dihydro-1H-inden-1-ylidene))dimalononitrile (BTP-4F), 2,2′-((2Z,2′Z)-((12,13-bis(2-butyloctyl)-3,9-diundecyl-12,13-dihydro-[1,2,5]thiadiazolo[3,4-e]thieno[2,′″:5′,6]pyrazino[2,3-g]thieno[3,′″:4′,5]thieno[2,3-b]indole-2,10-diyl)bis(methanylylidene))bis(5,6-difluoro-3-oxo-2,3-dihydro-1H-inden-1-ylidene))dimalononitrile (BTP-4F-12), 2,2′-((2Z,2′Z)-((12,13-bis(2-ethylhexyl)-3,9-diundecyl-12,13-dihydro-[1,2,5]thiadiazolo[3,4-e]thieno[2,′″:5′,6]pyrazino[2,3-g]thieno[3,′″:4′,5]thieno[2,3-b]indole-2,10-diyl)bis(methanylylidene))bis(5,6-dicyano-3-oxo-2,3-dihydro-1H-inden-1-ylidene))dimalononitrile (BTP-eC9), 2,2′-[[6,6,12,12-Tetrakis(4-hexylphenyl)-6,12-dihydro-6,12-diazapentacene-2,9-diyl]bis[methanylylidene (3-oxo-1H-inden-2-yl-1-ylidene)]]dimalononitrile (ITIC), 5,5′-[[4,4,9,9-Tetrakis(4-hexylphenyl)-4,9-dihydro-s-indaceno[1,2-b:5,6-b′]dithiophene-2,7-diyl]bis(2,1,3-benzothiadiazole-7,4-diyl)]bis(3-ethyl-2-thioxothiazolidin-4-one) (IDTBR), and 2,2′-[[6,6,12,12-Tetrakis(4-hexylphenyl)-6,12-dihydro-6,12-diazapentacene-2,9-diyl]bis[methanylylidene (5,6-difluoro-3-oxo-1H-inden-2-ylidene)]]dimalononitrile (IEICO-4F), but is not limited thereto. As a more preferred embodiment, the second electron acceptor material may be BTP-4F-12.

In the bulk heterojunction layer, the second electron acceptor material and the first electron donor material may have a mass ratio of, for example, 1:0.5 to 2, and specifically, in the case of the bulk heterojunction layer of PM6 and BTP-4F-12, the mass ratio may preferably be 1:1 to 1.5. However, this is not limited to the above-described example.

In conclusion, the photodetector according to the embodiment of the disclosure includes a novel multilayer structure capable of effectively separating charges formed by an optical signal and suppressing reverse charge flow by injected charges.

The electron acceptor thin film layer formed with a stable interface through the transfer printing process has the characteristic of suppressing dark current more than the existing structure by forming an effective injection barrier and effectively separating the generated photocharges through excellent electron affinity, thereby inducing an improvement in the response signal.

### Next, a Photodetector Manufacturing Method According to an Embodiment of the Disclosure Will be Described.

A method for manufacturing a photodetector according to an embodiment of the disclosure includes: applying a blocking layer composition on a first electrode (S100); coating a thin film layer including a first electron acceptor material on the first electrode to which the blocking layer composition is applied; forming a bulk heterojunction layer in which a second electron acceptor material and a first electron donor material are mixed through a transfer printing process on the thin film layer; and forming a second electrode on the bulk heterojunction layer.

First, a blocking layer is formed on the first electrode (S100).

The first electrode and the blocking layer are the same as those described in the description of the photodetector according to the embodiment of the disclosure.

In the step S100, before forming the blocking layer on the first electrode, a step of preprocessing the first electrode substrate may be further included. For example, a step of washing the first electrode substrate, performing ultrasonic treatment, and performing UV light treatment to improve wettability may be further included. However, the disclosure is not limited to these examples.

The blocking layer composition may be, for example, a ZnO nanoparticle solution when the blocking layer is ZnO.

As a means of forming the blocking layer, the blocking layer may be formed using spin coating, but is not limited thereto, and a known coating method may be used.

Next, a thin film layer is coated on the first electrode (S200).

Regarding the above thin film layer, it is the same as the content described in the description of the photodetector according to the embodiment of the disclosure, and the thin film layer includes a first electron acceptor material.

As a means for forming the thin film layer, for example, spin coating may be used to form the thin film layer, but is not limited thereto, and a known coating method may be used.

Next, a bulk heterojunction layer is formed on the thin film layer (S300).

At this time, in forming the bulk heterojunction layer, a transfer printing process is adopted to form a stable continuous structure in which the thin film layer does not dissolve by excluding solvent penetration into the thin film layer located below.

The transfer printing process corresponds to a method of forming a solid thin film on a desired surface in a solid state by drying the solvent using a polymer medium capable of controlling surface energy.

The medium may be, for example, a mold formed in the form of a film. That is, a bulk heterojunction layer is formed by bonding it within the mold, and it is peeled (separated) from the thin film layer.

In the above transfer printing process, the mold may be formed by mixing a plurality of polymer materials, and for example, in an embodiment of the disclosure described below, a mold film was produced from a mixture of aliphatic urethane diacrylate oligomer, 2-hydroxyethyl acrylate, and 1-hydroxycyclohexyl phenyl ketone.

In order to form the target material, the bulk heterojunction layer, on the blocking layer in the transfer printing process, the heterojunction layer needs to be separated from the mold corresponding to the medium, so it is necessary to optimize the temperature control by considering the glass transition temperature and surface energy of the polymer material constituting the mold. For example, the transfer printing process is most preferably performed in a temperature range of 373 K to 403 K when the blocking layer is ZnO, the thin film layer is PC₇₁BM, and the bulk heterojunction layer is PM6 and BTP-4F-12. When the process temperature is in the above-described range, the G value of the interface between the heterojunction layer and the mold is lower than the G value between the thin film layer and the blocking layer, so that uniform transfer is possible.

In addition, when performing the transfer printing process, the process speed at which the heterojunction layer is separated from the mold is most preferably performed in a range of 0.1 to 0.3 cm·s⁻¹. When the process speed is in the above-described range, the G value of the heterojunction layer and the mold interface is lower than the G value between the thin film layer and the blocking layer, so that uniform transfer is possible. For example, based on a heterojunction layer length of 1.5 cm in the mold, the peeling time can be performed in the range of 5 to 15 seconds.

Finally, a second electrode layer is formed on the formed heterojunction layer.

The second electrode also omits the same part as the content of the second electrode described above.

As a means for forming the second electrode, the second electrode may be formed using spin coating, but is not limited thereto, and a known coating method may be used.

Hereinafter, the disclosure will be described in more detail through manufacturing examples, comparative examples, and experimental examples. However, the disclosure is not limited to the following manufacturing examples and experimental examples.

### (Embodiment 1): Device Manufacturing

ITO on glass was used as the lower electrode.

Before fabrication of the device, the ITO substrate was physically cleaned with a cotton swab and sequentially sonicated in three solvents: deionized water, acetone, and isopropanol. In addition, the substrate was treated with UV light for 20 min to improve the wettability of the ZnO solvent.

Next, the ZnO nanoparticle solution was manufactured in ethanol at a concentration of 2 mg/mL and then spin-coated on the ITO substrate.

Next, to fabricate the acceptor-bulk-heterojunction (A/BHJ) structure (hereinafter, A/BHJ structure), a PC₇₁BM solution at a concentration of 10 mg/mL in chlorobenzene was formed on the ZnO layer and then annealed at 100° C. for 10 min.

Next, the BHJ solution was spin-coated on the ZnO layer or the PC71BM layer.

The above BHJ solution is composed of PM6 (Brilliant Matters), BTP-4F-12 (Brilliant Matters), and Eh-IDTBR (1-Materials), and has a concentration of 2.2 wt. % in o-xylene (PM6:BTP-4F-12 or PM6:Eh-IDTBR=1:1.2). Next, the BHJ film was annealed at 150° C. for 10 min. Molybdenum trioxide (MoO₃) (Sigma-Aldrich) was deposited on the BHJ layer with a thickness of 5 nm at a pressure of 5.0×10⁻⁶ Torr using a thermal evaporator, and silver was deposited on the MoO₃ layer with a thickness of 100 nm through thermal evaporation to form the top electrode.

To perform the transfer process, a mixture of aliphatic urethane diacrylate oligomer (EB 9270, ENTIS), 2-hydroxyethyl acrylate (HEA, Aldrich), and 1-hydroxycyclohexyl phenyl ketone (HCPK, Aldrich) was formed by mixing the mixture, which was applied to a silicon wafer and then exposed to UV light for 10 minutes to produce a mold film.

The transfer process of the A/BHJ structure was performed on the PC₇₁BM layer after forming a BHJ thin film on the mold film.

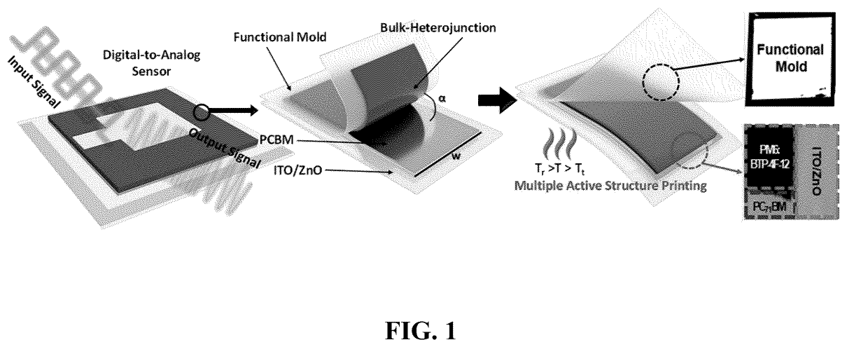

FIG. 1 is a schematic diagram showing a photodetector according to an embodiment of the disclosure, and the photodetector of embodiment 1 was produced by the process described above as in FIG. 1.

In addition, a hole-only element of an ITO/MoO3 (10 nm)/pure BHJ or A/BHJ structure (PC71BM/BHJ)/MoO3/Ag structure was additionally produced.

### Experimental Example 1: Transfer Printing Process

In the disclosure, the development of a transfer printing process that can clearly form two consecutive layers within the same solvent system while preventing the penetration of the solution into the lower layer for the generation of multiple layers was included (see FIG. 1). The first electron acceptor material constituting the thin film layer was used as a PC₇₁BM material known for its excellent conductivity. For the bulk heterojunction layer (BHJ), a PM6:BTP-4F-12 blend that is soluble in o-xylene was used.

In order for the target material to be successfully transferred to the target substrate, the solvent of the BHJ active layer must be easily separated from the mold in a dried state, so the adhesion between the BHJ active layer and the polymer mold was optimized based on the surface energy of the polymer mold. However, since the PC₇₁BM material applied to the acceptor layer has an amorphous structure, the bonding force with the lower substrate is weak, so the slip phenomenon easily occurs, and it is damaged when pressure is applied to the upper portion.

Specifically, the interfacial energy of PC₇₁BM and the lower electrode substrate was calculated using the Owen-Wendt-Rabel-Kaelble method, and the measured value was 7.36 mJ m⁻². This value was significantly lower than the interfacial energy of PC71BM and BHJ layer, which was determined to be 9.48 mJ m⁻² based on the contact angle measurement results. As a result, despite the control of the wetting coefficient between the BHJ layer and the mold, the PC71BM layer was partially torn, resulting in a short circuit between the anode and cathode, which prevented the device from operating.

Therefore, temperature control was used to control the interfacial adhesion to prevent the delamination of PC₇₁BM. This is because the adhesive behavior of the polymer is affected by the glass transition temperature (T_{g}). When T_{g} is reached, the bond between the polymer mold and the BHJ layer becomes weak, which contributes to the stable processability of transfer printing onto the PC₇₁BM layer. To evaluate the transcription process according to temperature, the energy release rate (G) was introduced using the formula in equation 1 below.

$$G = P / w \qquad ( Equation 1 )$$

In equation 1 above, P represents the peeling force and w represents the width.

The peeling force (P) may be expressed as the adhesion work (W) as shown in equation 2 below.

$$W = P ( 1 - cos α ) \qquad ( Equation 2 )$$

Here, α represents the peeling angle. In addition, W may be determined using equation 3 below.

$$W ( 1 - cos α ) + ( 1 / 2 ) ( {W}^{2} / Ewh ) = γ \cdot w \qquad ( Equation 3 )$$

Here, E is Young's modulus and h is the thickness of the film being peeled off. The Young's modulus of the mold film can be obtained from a universal tensile tester machine.

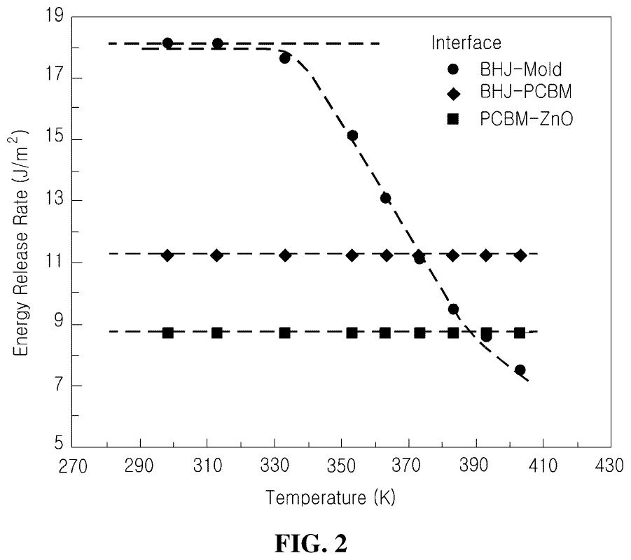

In the transfer printing process of the A/BHJ structure, the G value was determined for each interface (mold and BHJ, BHJ and PC₇₁BM, PC₇₁BM and ZnO) at various temperatures, as shown in FIG. 2. The T_{g} of PM6 is known to be 402 K. Therefore, when the process temperature was lower than T_{g}, the BHJ layer was not peeled off from the mold. As the temperature approached the T_{g} of the BHJ, the adhesion between the mold and the BHJ layer became weaker than that between the PC₇₁BM and BHJ layers, and the two polymers were separated.

Meanwhile, the BHJ layer was successfully transferred to the PC₇₁BM layer at 383 K, which is lower than the T_{g} of PM6, due to the BHJ structure with BTP-4F-12. However, above 393 K, the PC₇₁BM was delaminated from the lower substrate. The experimental results were plotted as the relationship between G and T (equation 4 below) over the temperature range of 293 to 403 K, as shown in FIG. 2.

$${G}_{interface} ( T ) = - {e}^{n} ( T - {T}_{g} ) + {G}_{0} \qquad ( Equation 4 )$$

In equation 4 above, n is a parameter that varies depending on the interface and G0 is the initial energy release rate. The G₀ values were determined to be 18.12, 11.21, and 8.71 J m⁻² at the BHJ/mold, BHJ/PC₇₁BM, and PC₇₁BM/ZnO interfaces, respectively.

As mentioned above, when the process temperature exceeded 373 K, the G value of the BHJ layer-mold interface was lower than that of the BHJ layer/PC₇₁BM layer interface due to the transfer temperature (Tt), so the BHJ layer was uniformly transferred from the mold to the PC₇₁BM layer. However, when the G value of the BHJ layer/mold interface was lower than that of the PC₇₁BM layer/ZnO interface, the PC₇₁BM layer tended to attach to the BHJ layer and detach from the ZnO.

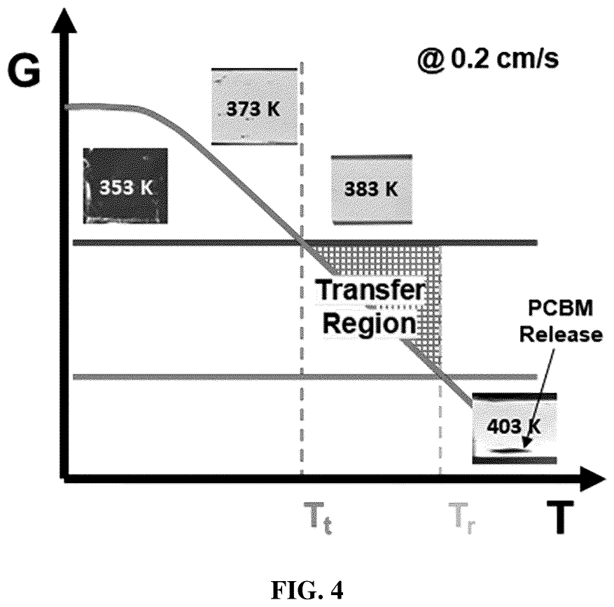

In addition, the experimental observations revealed that G depended on the velocity (FIG. 4). When the processing speed exceeded 0.3 cm·s⁻¹ or fell below 0.1 cm·s⁻¹, complete transfer printing of the BHJ layer did not occur. As a result, the G-v relationship could be plotted using the following equation.

$${G}_{interface} ( T , v ) = ( - {e}^{n} ( T - {T}_{g} ) + {G}_{0} ) ( 1 + {( v / {v}_{0} )}^{r} ) \qquad ( Equation 5 )$$

Here, v is the process speed, v₀ is the reference speed, and r is the fitting parameter.

Using equation 5 above, the processing speed was optimized to 0.2 cm s⁻¹. As a result, when the process temperature was within the range of Tₜ to Tᵣ, the BHJ layer was transferred onto the PC₇₁BM as shown in FIG. 4. Conversely, when the OPD was manufactured at a temperature outside this range, a short circuit was observed in the device.

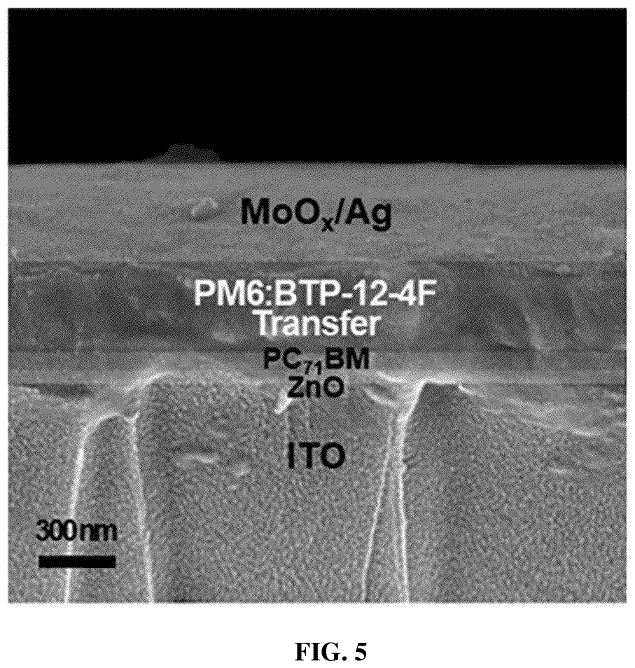

To confirm the formation of the A/BHJ structure through transfer printing, a scanning electron microscope (SEM) cross-sectional analysis was performed (FIG. 5). The thicknesses of the pure BHJ film and the BHJ film on the PC₇₁BM were almost the same (≈360 nm), and as shown in FIG. 5, the thickness decreased slightly (<10 nm) after the transfer process.

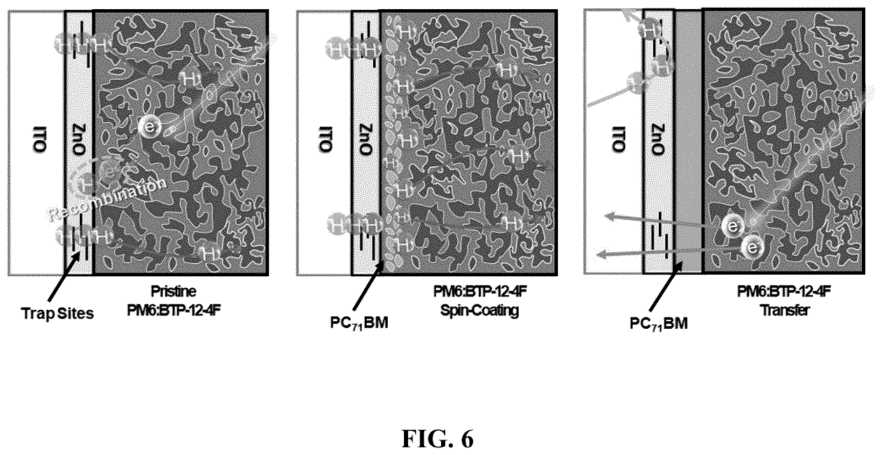

In contrast, the A/BHJ structure obtained by spin coating showed a mixture of PC₇₁BM and BHJ layers in the cross-sectional image obtained through SEM despite the use of different solvents. That is, it was concluded that only the A/BHJ structure implemented through transfer printing rather than spin coating, as shown in FIG. 6, effectively suppressed the injection current and improved the transport of the photogenerated current by preventing recombination at the trap sites of ZnO.

Nevertheless, in the case of the A/BHJ structure created by spin coating using a mixture of BHJ and PC₇₁BM, PC₇₁BM acted as a photosensitive layer that amplified the current at the interface due to the increased number of trap sites (FIG. 6).

### Experimental Example 2: Dark Current Reduction and Photocurrent Enhancement Characteristics of A/BHJ Structure

To investigate the energy levels of the A/BHJ structure, ultraviolet photoelectron spectroscopy (UPS) analysis was performed. This allowed the direct determination of the hole injection barrier at the interface between the electrode and the semiconductor. The UPS results facilitated this evaluation by determining the cutoff point of the binding energy. In addition, the UPS results were calibrated using a gold substrate, and an indium tin oxide (ITO) substrate was used to observe the hole injection barrier energy from ITO.

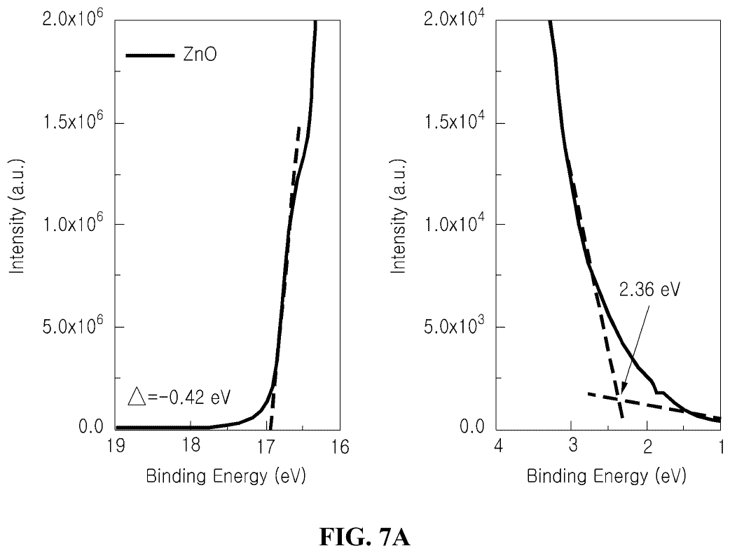

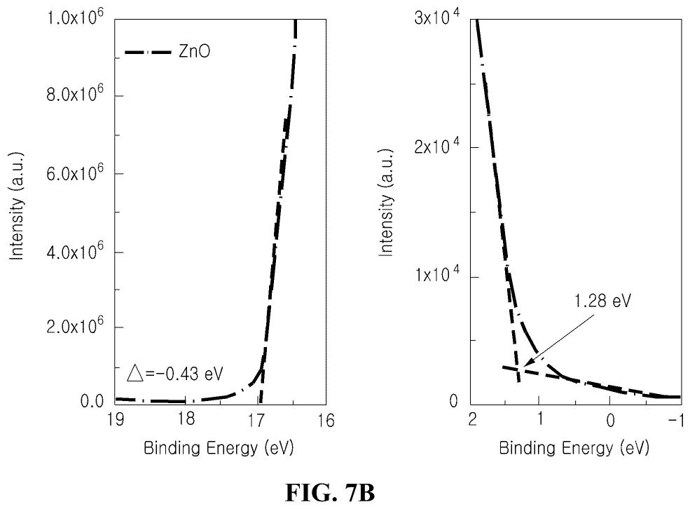

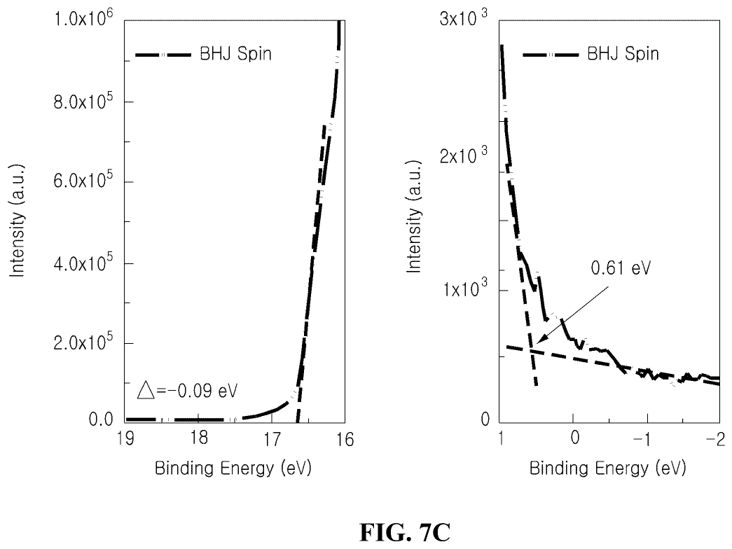

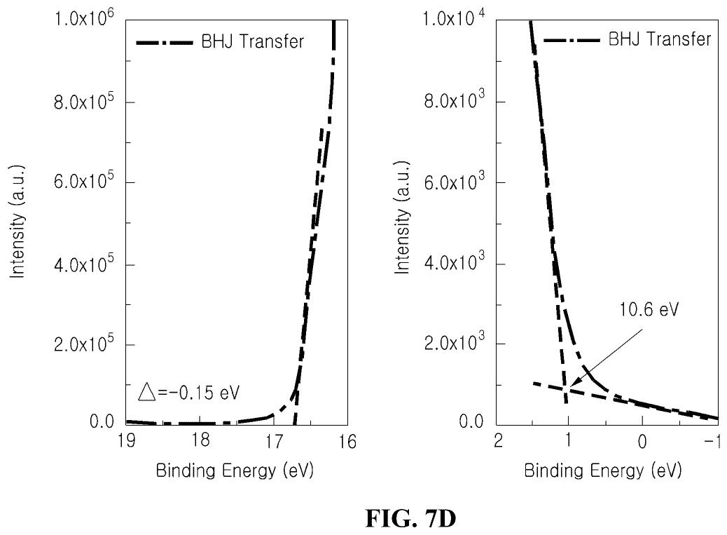

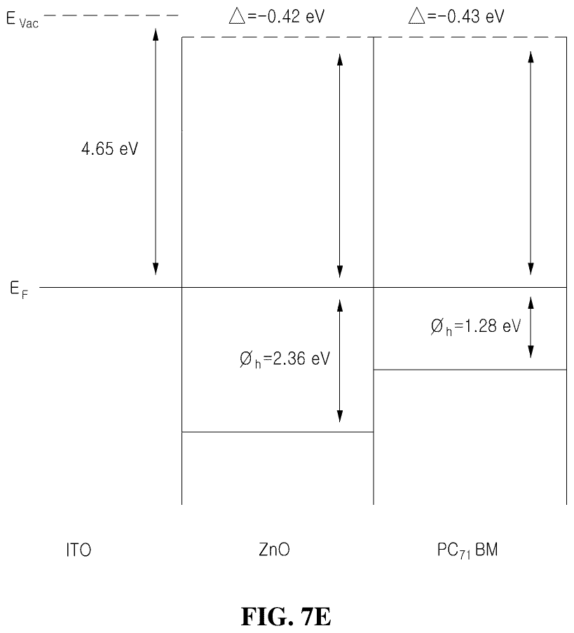

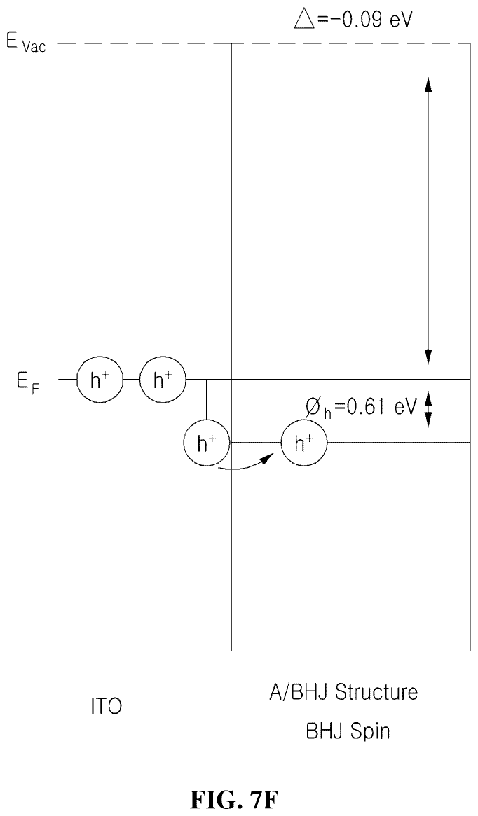

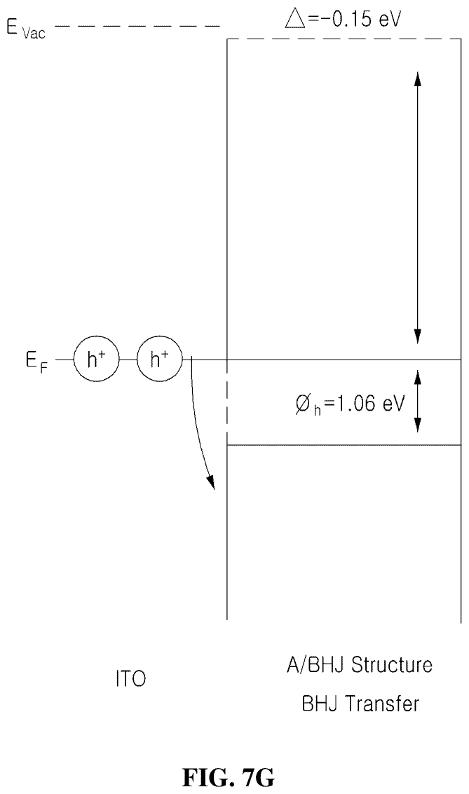

First, the work function of the ITO surface (−4.65 eV) was obtained from the UPS results. The hole injection barrier energies of ZnO and PC71BM were determined to be 2.36 eV and 1.28 eV, respectively (FIGS. 7A, 7B, and 7E). In addition, both films showed significant vacuum level shifts (0.42 eV and 0.43 eV, respectively) with respect to ITO, indicating a significant dipole difference with respect to the ITO electrode. This shift may be attributed to the trap sites on the ZnO surface.

The hole injection barrier energy is greatly affected by the depth of the highest occupied molecular orbital (EHOMO) of the donor or acceptor. The shallow EHOMO of PM6 was expected to play a pivotal role in determining the hole injection barrier energy. The hole injection barrier energy was significantly affected by the contact with PC₇₁BM due to the formation of the A/BHJ structure in which the BHJ layer does not directly contact the electrode. To evaluate the hole injection barrier of the photoactive layer with the A/BHJ structure according to the process, UPS analysis was performed (FIGS. 7C, 7D, 7F, and 7G).

ZnO was not included in the UPS analysis because it was difficult to accurately determine the injection barrier energy due to its UV reactivity. The results showed that the A/BHJ structure formed through spin coating exhibited a lower hole injection barrier energy of 0.61 eV due to the EHOMO of PM6 (−5.30 eV), which is a result of the formation of a mixture of BHJ and PC71BM.

In contrast, the A/BHJ structure formed through transfer printing resulted in an increase in the hole injection barrier energy. This increase corresponds to the result of the continuous formation of multiple structures on the ITO electrode. As a result, the A/BHJ structure formed through transfer printing was proven to be effective in reducing charge injection from the ITO anode.

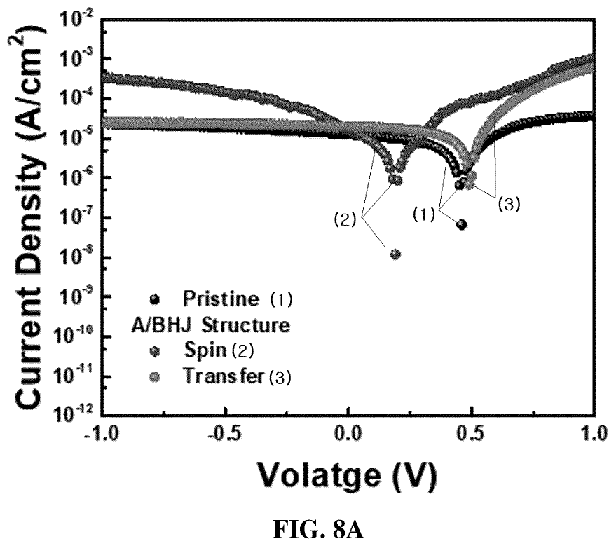

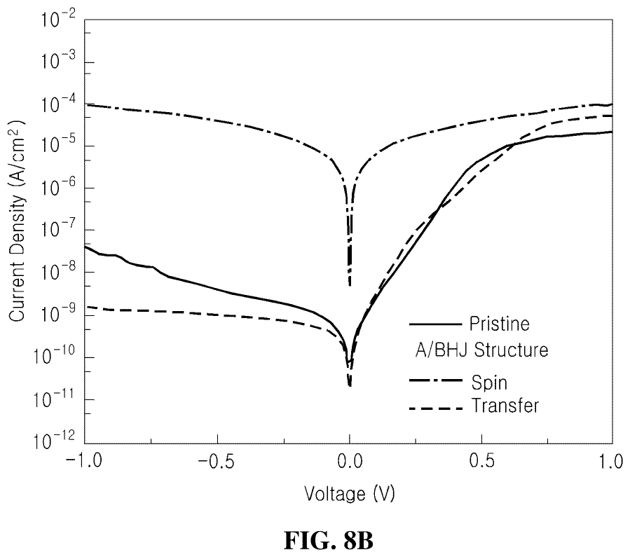

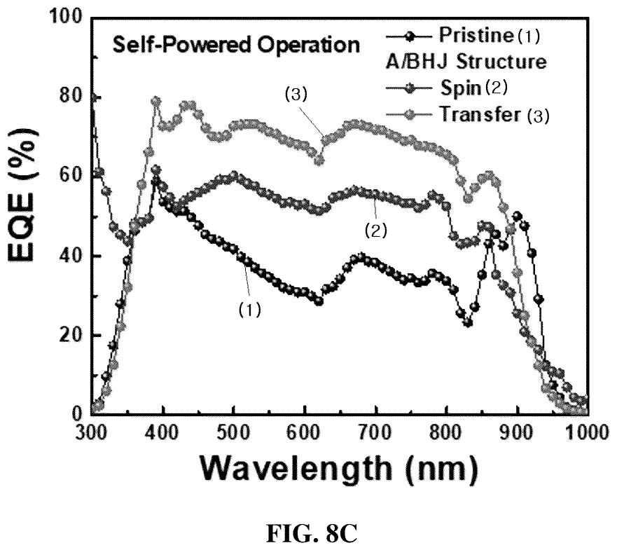

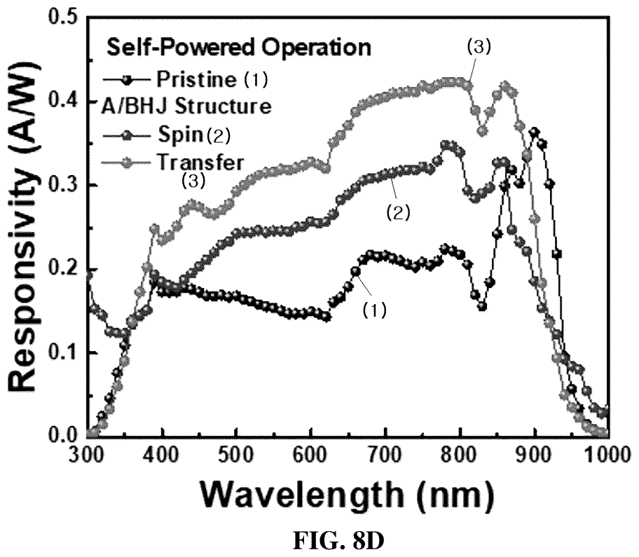

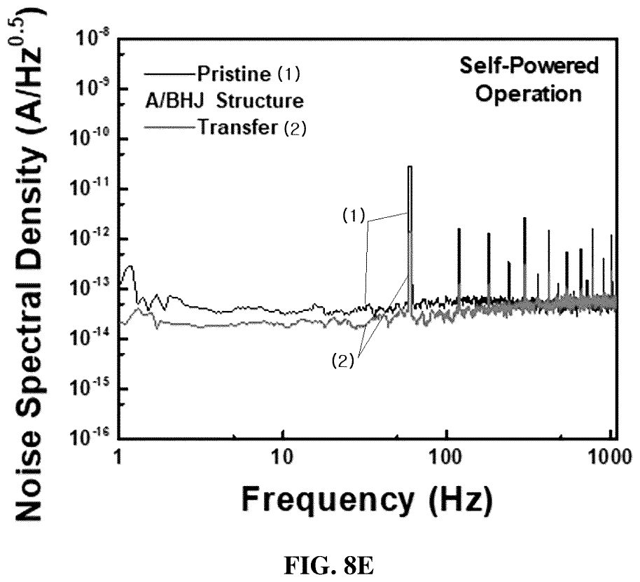

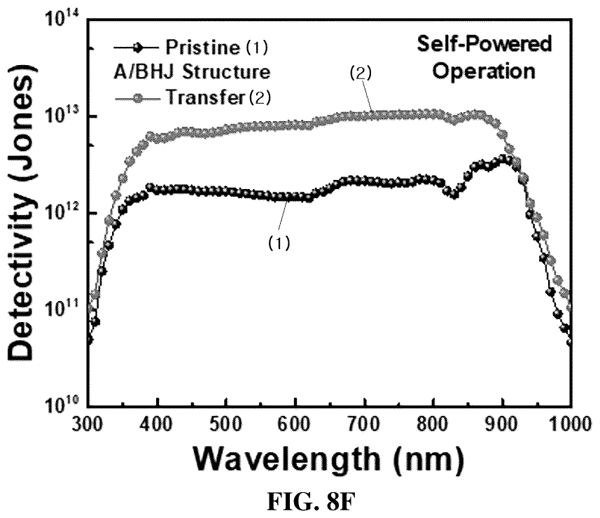

Next, the current density-voltage (J-V) characteristics of the OPD with the pure BHJ layer and the A/BHJ structure were evaluated under illumination and dark conditions (FIG. 8A, FIG. 8B). Compared with the pure OPD, the OPD with the A/BHJ structure obtained through transfer printing exhibited a higher photocurrent. This increase is due to the accelerated electron transport of the PC₇₁BM layer present in the A/BHJ structure. Interestingly, although it exhibited a lower open-circuit voltage, the A/BHJ structure prepared by spin coating showed an increase in photocurrent due to the mixing of the BHJ and acceptor layers. Therefore, this behavior suggests a photomultiplication phenomenon resulting from the high interfacial trap density of the photosensitized PC71BM layer.

The dark J-V curves of the OPD with the pure BHJ layer and the A/BHJ structure fabricated using different processes showed differences (FIG. 8B). The dark J-V curve of the OPD was obtained after a voltage sweep under illumination at 590 nm wavelength and 12 μW cm⁻² for stabilization of the photogenerated charge flow, which corresponds to a value similar to that in a previous study. The dark J-V curves showed lower dark current before UV irradiation. The A/BHJ structure obtained by transfer printing contributed to a significant 4-fold dark current reduction (1.68×10⁻⁹ A/cm²) at −1 V compared to the pure device (4.33×10⁻⁸ Acm⁻²). The unbiased dark current is mainly affected by the thermionic emission current, which is inversely proportional to the hole injection barrier energy. A higher current in the forward direction is observed in the device with the A/BHJ structure obtained by transfer process, indicating that the PC₇₁BM layer contributes to the series resistance reduction. Therefore, the higher energy barrier of the A/BHJ structure obtained by transfer printing led to the suppression of the dark current. Conversely, the increased trap sites due to the photosensitized PC₇₁BM layer of the A/BHJ structure obtained by spin coating caused a higher dark current, which negatively affected the OPD performance.

The dark current due to charge injection follows various models, including direct tunneling and trap-assisted tunneling. The direct tunneling current is mainly determined by the hole injection barrier energy, while the trap-assisted tunneling current arises from defect states within the device system. As a result, the A/BHJ structure produced by spin coating showed a significant increase in dark current under reverse bias due to the trap-assisted tunneling effect induced by the photosensitized PC₇₁BM layer. In contrast, the A/BHJ structure obtained by transfer printing showed much lower dark current under reverse bias conditions. This is due to the higher hole injection energy barrier.

The effect of the A/BHJ structure achieved through transfer printing was also shown in the external quantum efficiency (EQE) spectrum (FIG. 8B). The pure device with the ≈120 nm thick active layer showed an EQE value exceeding 80% in the visible region, but the EQE value dropped below 60% for the thicker active layer under pure conditions due to higher charge recombination. The EQE value of the A/BHJ structure obtained through transfer printing showed an improvement in most wavelength ranges despite the thick active layer. In addition, the device with the 120 nm thick A/BHJ structure showed an improved EQE compared to the BHJ device in the wavelength range of 550-850 nm. The higher EQE of the A/BHJ structure indicates improved charge collection independent of the PC₇₁BM absorption, highlighting the effectiveness of charge carrier collection in this particular structure configuration. The valley in the EQE spectrum is caused by the xenon lamp, as confirmed by the Si reference cell.

The internal quantum efficiency (IQE) was measured to investigate the effect of the A/BHJ structure fabricated by transfer printing on the EQE enhancement. The device with the A/BHJ structure fabricated by transfer printing exhibited a higher IQE than the other devices, achieving an IQE of nearly ≈80% despite the 360 nm thick active layer, which means that most of the incident photons were converted into charge carriers and extracted. This improvement was driven by the effective charge collection at the interface between the BHJ layer and the PC₇₁BM layer, which accelerates charge transport and reduces charge recombination. Since PC71BM has a favorable LUMO energy level and contributes to the deactivated surface trap sites, a cascade energy structure that enhances charge collection is formed in the device with the A/BHJ structure.

### Experimental Example 3: Specific Detection Rate Enhancement Performance of A/BHJ Structure

The specific detection rate (D*), which is a performance indicator of PD devices, was determined based on the relationship between the sensitivity (R) and the noise spectral density (Sn) using equation 6 below.

$${D}^{*} = \frac{R \sqrt{A}}{{S}_{n}} = \frac{\frac{{J}_{p h}}{{L}_{light}} \sqrt{A}}{{S}_{n}} \qquad ( Equation 6 )$$

Here, Jₚₕ is the photocurrent density, L_{light} is the incident light density, A is the device area, and Sn is the noise spectral density.

FIG. 8D shows the R value as a function of wavelength. The R value of the device with the A/BHJ structure prepared by transfer printing exceeded the R value of the other devices without bias due to the reduction of charge recombination. Meanwhile, the EQE and responsivity results at −0.5 V showed an EQE exceeding 10,000%, which enhanced the photomultiplication effect of the A/BHJ structure prepared by spin coating, indicating the presence of traps in the PC71BM layer. However, the device with the A/BHJ structure prepared by transfer printing maintained the EQE and responsivity under reverse bias, indicating that the A/BHJ structure prepared by transfer printing has little or no surface traps.

FIGS. 8E and 8F show the calculated Sn and D as a function of wavelength when there is no bias voltage, respectively. The A/BHJ structure fabricated by transfer printing showed a noise reduction of less than 10⁻¹³ A/Hz 0.5, due to the defect passivation of ZnO and the favorable structure by the transfer process, considering the background noise of the measurement equipment. On the other hand, the pure device exhibited higher Sn values over the entire frequency range, which negatively affected the D value. The D* value was calculated using the average value of Sn from 100 Hz to 1 kHz. The A/BHJ structure fabricated by transfer printing showed a significantly improved D* value (1.06×1013 Jones), which is more than 7 times higher than the pure device performance over the entire wavelength range.

Next, to demonstrate the generality of the manufacturing method of the disclosure, the A/BHJ structure was prepared by transfer printing in another BHJ system consisting of PM6 and 5,5′-[[4,4,9,9-tetrakis(2-ethylhexyl)-4,9-dihydro-s-indaceno[1,2-b:5,6-b□]dithiophene-2,7-diyl]bis(2,1,3-benzothiadiazole-7,4-diylmethylidyne)]bis[3-ethyl-2-thioxo-4-thiazolidinone] (Eh-IDTBR). These devices showed lower dark current and higher photocurrent than the spin-coated PM6:Eh-IDTBR devices. The noise current of the OPD with the A/BHJ structure with the transferred PM6:Eh-IDTBR was reduced to 9.78×10⁻¹⁵ A/Hz^{0.5} due to the dark current suppression effect of PM6:Eh-IDTBR, resulting in an enhanced detectivity of 2.01×1014 Jones. As a result, the A/BHJ structure fabricated by transfer printing satisfied both the efficient OPD requirements of excellent dark current suppression and significant photocurrent enhancement.

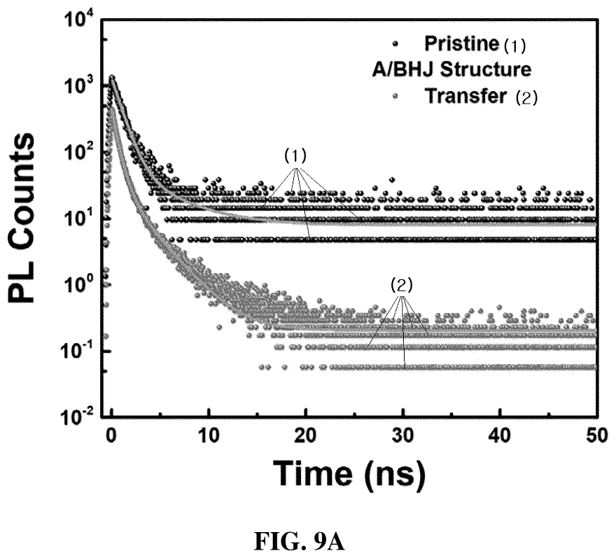

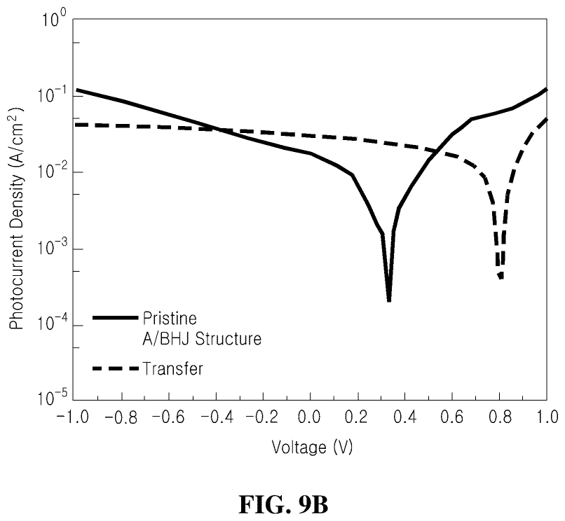

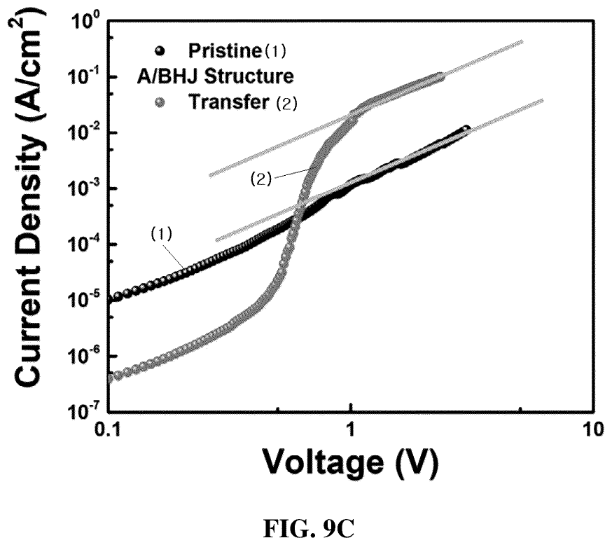

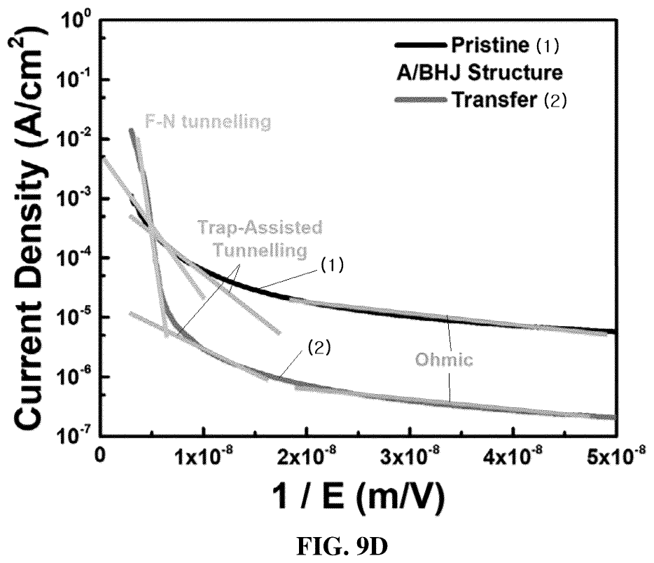

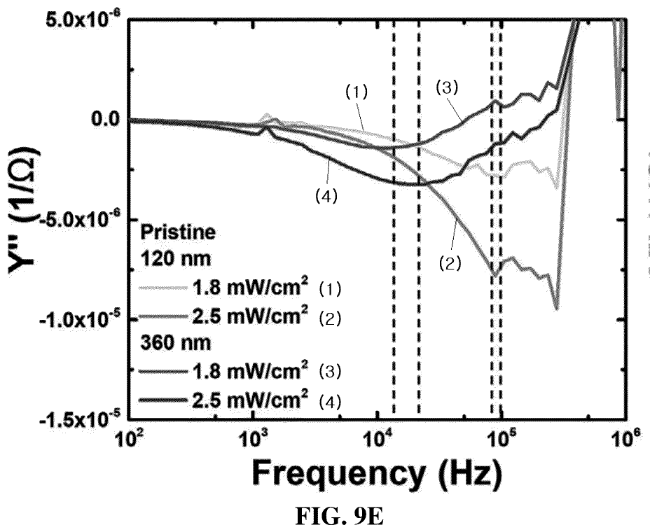

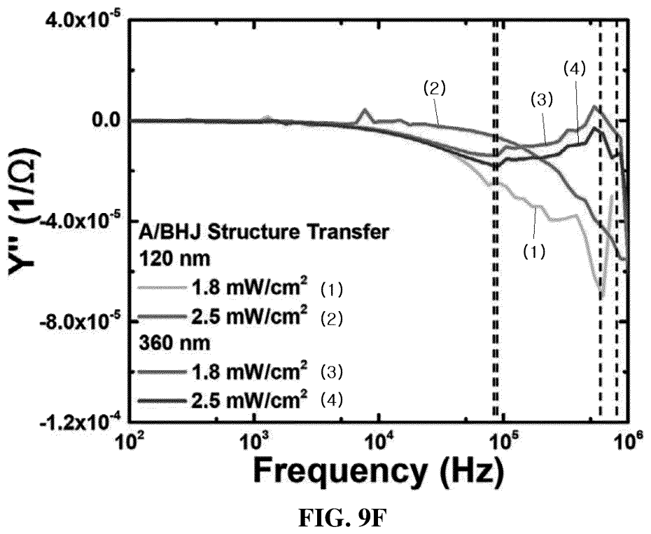

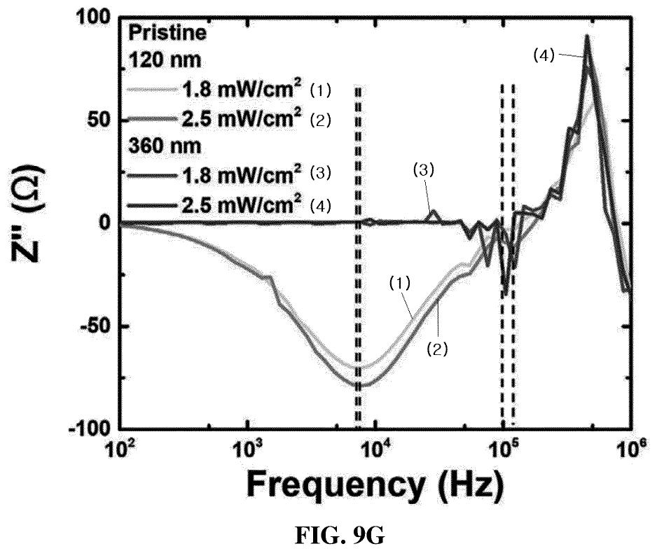

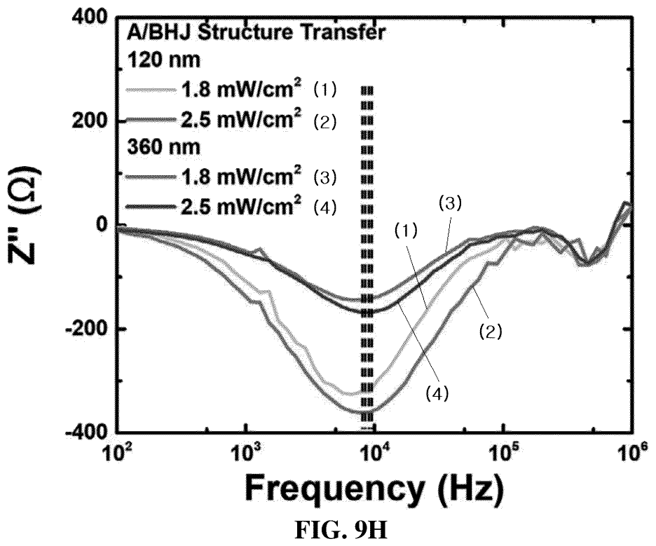

To better understand each active layer at the interface with ZnO, time-resolved photoluminescence (TRPL) was investigated using time-correlated single photon counting (TCSPC), as shown in FIG. 9A. The steady-state PL of the PC71BM/BHJ structure obtained by transfer printing is much quenched compared to that of the pure BHJ structure without the PC71BM layer. The PL lifetime of the PC₇₁BM/BHJ structure obtained by transfer printing was much shorter than that of the pure BHJ structure without the PC₇₁BM layer. The shorter PL lifetime observed in the PC₇₁BM/BHJ structure obtained by transfer printing is likely due to the additional quenching of excitons by the PC₇₁BM layer.

FIG. 9B is a J-V plot of a photodetector according to an embodiment of the disclosure.

To investigate the internal potential of the OPD structure, the OPD was fabricated and the compensation voltage was analyzed by analyzing the current generated under light irradiation conditions (FIG. 9B). The compensation voltage and the internal potential are proportional. The compensation voltage of the A/BHJ structure was much higher than that of the pure BHJ. Therefore, it can be inferred that the A/BHJ structure obtained by transfer printing suppressed the recombination occurring at the interface due to the passivation effect.

A hole-only device was fabricated to investigate the trap density of the OPD structure. Then, the trapped space charge limited current (SCLC) characteristics under dark conditions were analyzed using the following device structures: ITO/MoO₃/pure BHJ or A/BHJ structure (PC₇₁BM/BHJ)/MoO₃/Ag (see FIG. 9C). The hole mobility of the A/BHJ structure was 1.65×10⁻³ cm² V⁻¹ s⁻¹, which was much higher than that of the pure structure (8.59×10⁻⁵ cm² V⁻¹ s⁻¹). Therefore, it can be inferred that the A/BHJ structure obtained through transfer printing contributed to the photocurrent enhancement due to the improved hole mobility. Equation 7 below represents the trap-assisted tunneling behavior as follows.

$$J ∝ exp ( - \frac{8 π \sqrt{2 m * {Φ}_{t}^{3}}}{3 hqE} ) \qquad ( Equation 7 )$$

Here, m is the effective mass of charge carriers, Φₜ is the energy state due to the defect, h is Planck's constant, and E is the electric field of the OPD (E=V/d).

To calculate Φₜ, we assumed a value of m* equal to 0.38 me according to previous studies, and as a result, we determined the approximate value of Φₜ by checking the slope of ln J vs. 1/E.

At low electric fields, direct tunneling through the ohmic contact is the main charge transfer mechanism because the bias is not sufficient to facilitate the transition of charge carriers to other energy states.

Conversely, at high electric fields, charge carriers are injected to the opposite electrode through the energy levels of the semiconductor via Fowler-Nordheim (F-N) tunneling.

In the middle, charge carriers can be transferred to the defect states of the semiconductor, which indicates trap-assisted tunneling. Trap-assisted tunneling was not observed under reverse bias conditions due to the V_{bi} of the diode structure of the OPD.

To obtain the defect status of each device, the dark J-V characteristics under forward bias were analyzed using the relationship between ln J and 1/E as shown in FIG. 9D. The extracted Φₜ values were 0.12 eV for the device with a pure active layer and 0.06 eV for the A/BHJ structure obtained by transfer printing. The reduced Φₜ of the A/BHJ structure compared to the deep Φₜ of the pure device suggests the improved charge carrier behavior exhibiting trap passivation and hole injection blocking characteristics. Therefore, the well-formed A/BHJ structure was proven to be a suitable choice for OPD, resulting in both enhanced photocurrent and reduced dark current.

To analyze the charge transport and charge recombination according to the active layer structure, intensity-modulated photocurrent spectroscopy (IMPS) and intensity-modulated photovoltage spectroscopy (IMVS) were performed as shown in FIG. 9E to FIG. 9H and Table 1.

TABLE 1

| | Sensitive | | Light | | | | |
|---|---|---|---|---|---|---|---|
| Active | layer | | intensity | τₜᵣ | τ_{rec} | D | L_{D} |
| layer | thickness | | [mW cm⁻²] | [s] | [s] | [cm² s⁻¹] | [nm] |
| BHJ | 120 | nm | 1.8 | 1.84 × 10⁻⁶ | 2.09 × 10⁻⁵ | 3.35 × 10⁻⁵ | 264 |
| | | | 2.5 | 1.81 × 10⁻⁶ | 2.03 × 10⁻⁵ | 3.39 × 10⁻⁵ | 262 |
| | 360 | nm | 1.8 | 1.32 × 10⁻⁵ | 1.33 × 10⁻⁵ | 4.18 × 10⁻⁵ | 75 |
| | | | 2.5 | 7.29 × 10⁻⁶ | 1.52 × 10⁻⁵ | 7.57 × 10⁻⁵ | 107 |
| A/BHJ | 120 | nm | 1.8 | 2.61 × 10⁻⁷ | 2.14 × 10⁻⁵ | 2.35 × 10⁻⁵ | 709 |
| Structure | | | 2.5 | 1.95 × 10⁻⁷ | 1.99 × 10⁻⁵ | 3.14 × 10⁻⁵ | 791 |
| Transfer | 360 | nm | 1.8 | 2.02 × 10⁻⁶ | 2.12 × 10⁻⁵ | 2.73 × 10⁻⁵ | 761 |

| | | | | |
|---|---|---|---|---|
| 2.5 | 1.73 × 10⁻⁶ | 1.86 × 10⁻⁵ | 3.19 × 10⁻⁵ | 770 |

Under short-circuit conditions, the semiconductor exhibits a maximum band gap, minimizing electron injection into the conduction band. As a result, the main reaction occurs at the electrode, where electrons move from the generation point to the electrode.

Conversely, the open circuit potential represents the maximum potential of the device before power dissipation, as opposed to power generation. At this potential, the band gap between the HOMO and LUMO energies is small, reducing the possibility of reaction at the electrode. Most of the generated photoelectrons are injected into the LUMO energy of the semiconductor. In addition, the device reaches a steady state at the open circuit potential, which represents an equilibrium between the electron injection rate into the LUMO energy and the electron recombination rate. The curves exhibit a minimum at the intermediate frequency in the IMPS and IMVS spectra. These points in the IMPS and IMVS correspond to the characteristics of charge transport and charge recombination, respectively. Therefore, the electron transport time (Òtr) can be extracted from the IMPS spectrum, and the electron recombination time (Òrec) can be extracted from the IMVS spectrum.

The diffusion coefficient (D) and diffusion length (LD) can be obtained from equations 8 and 9 below.

$$D = \frac{{L}^{2}}{2.35 \cdot {τ}_{tr}} \qquad ( Equation 8 )$$

$${L}_{D} = \sqrt{D \cdot {τ}_{rec}} \qquad ( Equation 9 )$$

Here, L corresponds to the thickness of the active layer. In FIGS. 4e and 4f, the device with the A/BHJ structure shows a 10-fold decrease in Òₜᵣ compared to the pure device due to the enhanced charge transport at the interface facilitated by the PC₇₁BM layer.

When the diffusion coefficient is evaluated while considering the thickness, the A/BHJ structure maintains a constant level (3.14× 10⁻⁴ cm s⁻¹ and 3.19×10⁻⁴ cm s⁻¹, respectively) regardless of the thickness.

In contrast, the pure device shows a reduced diffusion coefficient (3×10⁻⁵ cm s⁻¹), which further decreases (8×10⁻⁵ cm s⁻¹) as the thickness increases, suggesting a lower thickness limitation of the BHJ system compared to the 360 nm condition.

In addition, notable differences in the recombination characteristics are observed between the devices with the pure BHJ and A/BHJ structures. The A/BHJ structure maintains a constant Òrec (1.99×10⁻⁵ s and 1.86×10⁻⁵ s) as the thickness increases, while the BHJ device shows a sharp decrease in Òrec (from 2.09×10⁻⁵ s to 1.33×10⁻⁶ s) at a thickness of 360 nm. The LD for each condition was calculated, and the A/BHJ structure contributed to a diffusion length exceeding 700 nm, indicating effective charge collection. In contrast, the BHJ showed a diffusion length of 264 nm at a thickness of 120 nm and less than 100 nm at a thickness of 360 nm due to trap sites arising from direct contact with ZnO. Therefore, it is concluded that the A/BHJ structure exceeds the thickness limit of PM6:BTP-4F-12 compared to the conventional BHJ. In addition, the A/BHJ structure suppresses charge recombination, which causes EQE loss due to reduced trap density and charge injection.

### Experimental Example 4: Response Speed Performance of A/BHJ Structure

Since the response speed is an important factor in evaluating the PD, the fall time analysis was performed based on the presence of light and the transient photocurrent as a function of frequency.

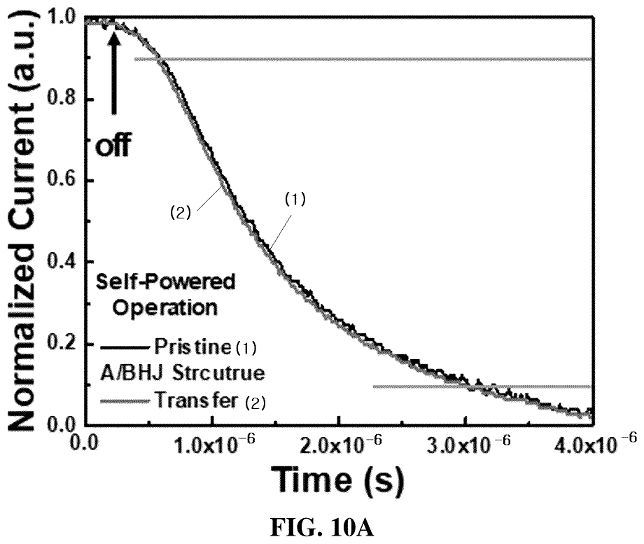

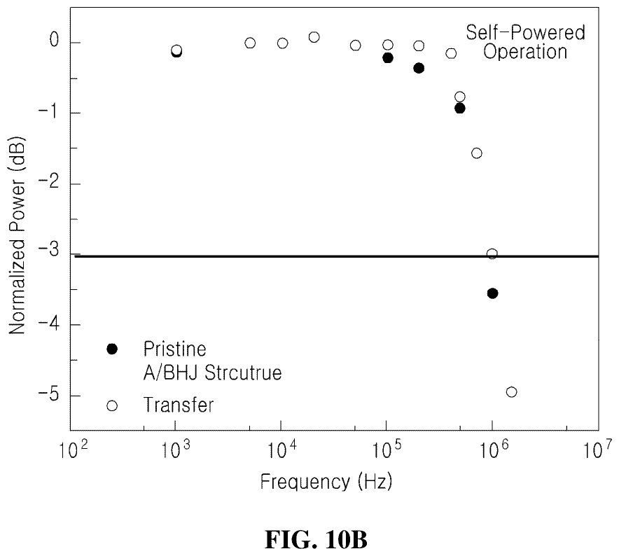

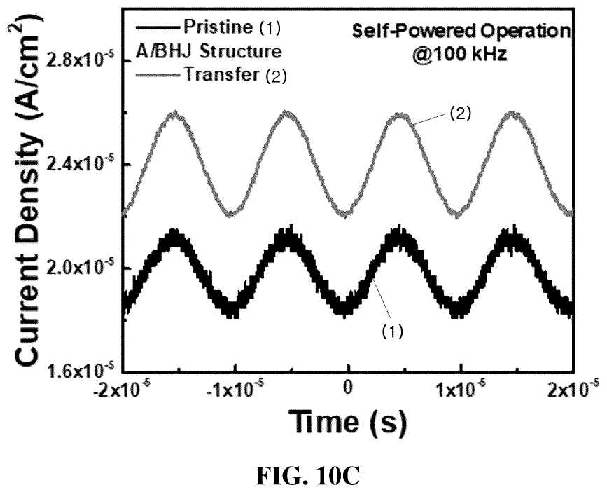

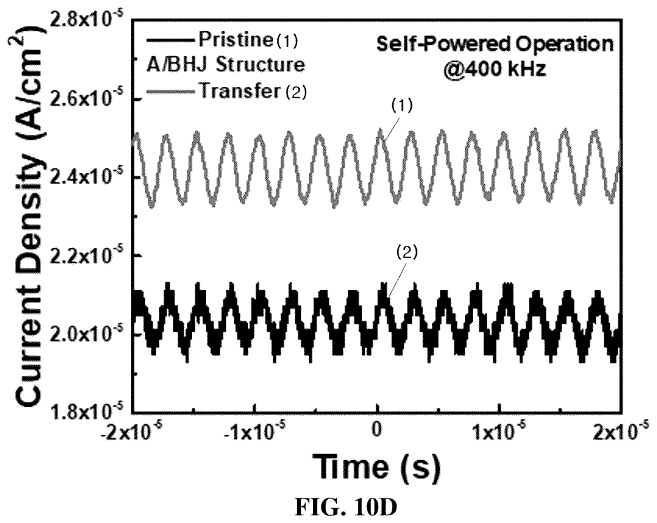

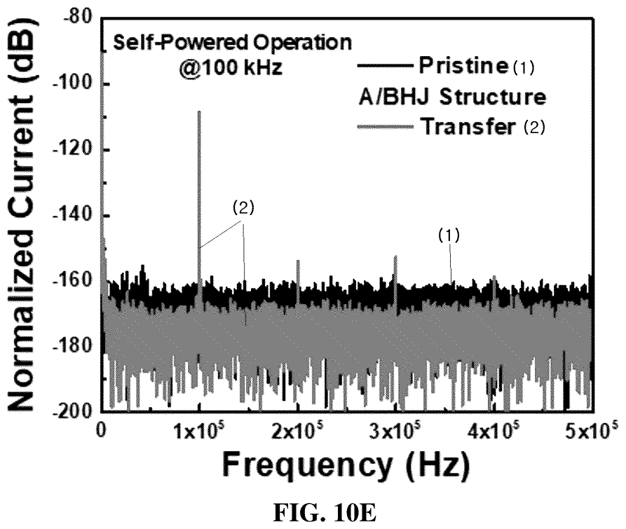

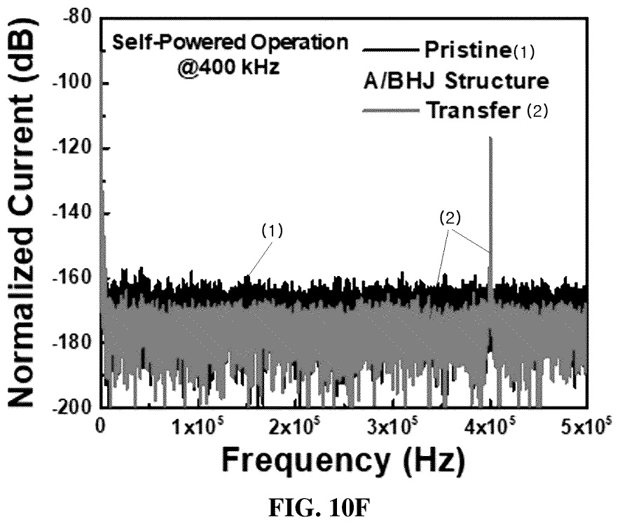

The BHJ device and the device with the A/BHJ structure made by transfer printing showed similar fall time values ((Òfall) of 2.64 and 2.37 μs, respectively (FIG. 10A), which were limited by the bandwidth of the amplifier. Meanwhile, the device with the A/BHJ structure made by transfer printing showed a similar level of rise time (2.32 μs) while showing suppressed noise current in the signal due to trap passivation.

In order to evaluate the analog signal receiver characteristics of the OPD, a sine-wave type light was irradiated on the OPD due to the square-wave detection that is affected by noise signals unlike the square-wave.

The results of the transient photocurrent analysis according to the frequency at the irradiation power of 1.8 to 2.5 mW cm⁻² showed that the A/BHJ structure-based device showed an excellent cutoff frequency (f₋₃ dB) of 1.02 MHz corresponding to the on-off ratio result, unlike the pure device (f₋₃ dB=847 kHz) (table 2).

The enhanced response speed due to the suppressed recombination due to the A/BHJ structure enabled the ultra-high-speed transmission of high-resolution information related to light. In addition, the pure device showed a reduced transient photocurrent, but the frequency-dependent photocurrent analysis results showed a higher noise current that negatively affected the main signal, as shown in FIGS. 10C and 10D.

In particular, the photocurrent of the pure device showed a high noise level that made it difficult to distinguish the main signal under a 400 kHz pulse signal.

To estimate the influence of noise in detail, SNR analysis was performed through fast Fourier transform (FFT) calculations as shown in FIGS. 10E and 10F. Interestingly, the FFT calculation results for the transient photocurrent of the BHJ device showed a higher current distribution around the main signal related to the shot noise, which lowered the SNR value to 41.0 dB. The noise current was mainly observed at 100 kHz, but in the pure device, it worsened the SNR value to 31.3 dB at 400 kHz.

However, the device with the A/BHJ structure made by transfer printing showed a clear signal with a lower noise current level even at 400 kHz pulse signal. The SNR values of the A/BHJ structure were extracted as 56.3 dB and 47.5 dB at 100 kHz and 400 kHz, respectively (table 2).

As a result, the OPD with the A/BHJ structure fabricated by transfer printing with the advantages of efficient charge extraction and noise suppression enabled high-frequency optical signal detection independent of the influence of noise. In addition, when comparing the power spectral density of the transient photocurrent as a function of frequency, the BHJ device exhibited a higher noise signal than the device with the A/BHJ structure, which implies that the A/BHJ structure contributes to noise suppression under illumination by enhancing the transport channel and passivating the defect sites.

TABLE 2

| | τ_{fall} | f₋₃ _{dB} | SNR at 100 kHz | SNR at 400 kHz |
|---|---|---|---|---|
| Active layer | [μs] | [Hz] | [dB] | [dB] |
| BHJ | 2.64 | 8.47 × 10⁵ | 41.0 | 31.3 |
| A/BHJ | 2.37 | 1.02 × 10⁶ | 56.3 | 47.5 |
| Structure | | | | |
| Transfer | | | | |

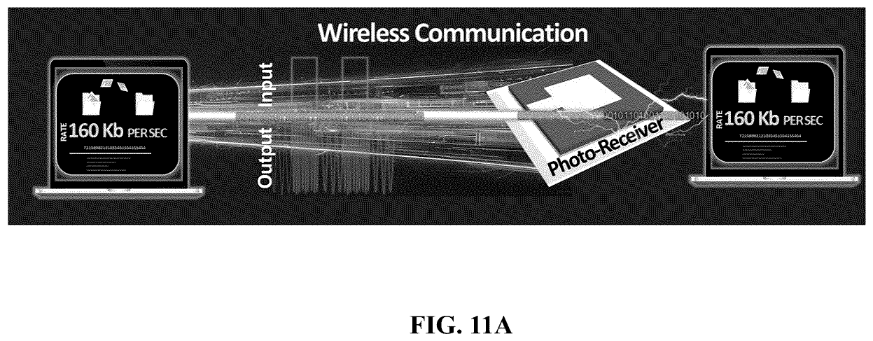

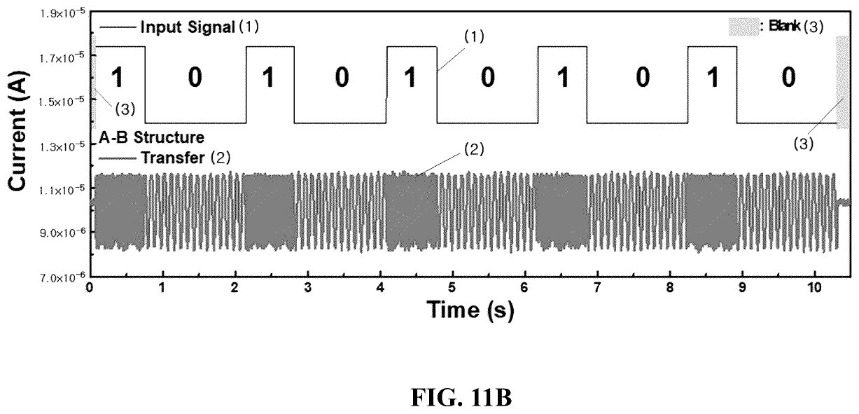

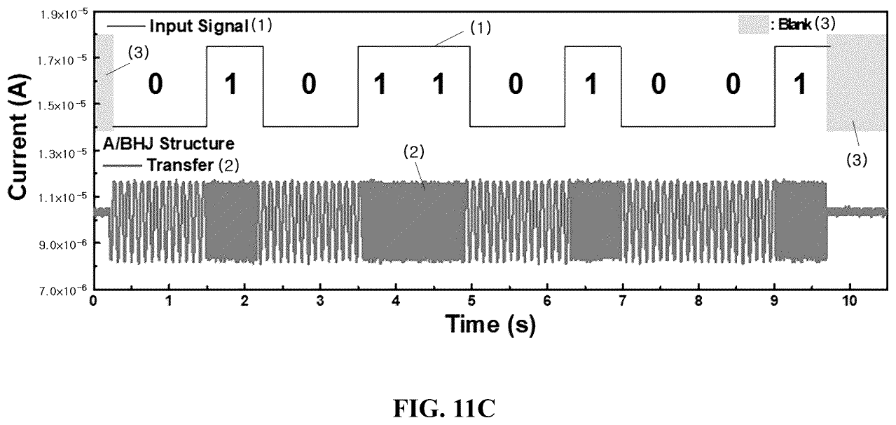

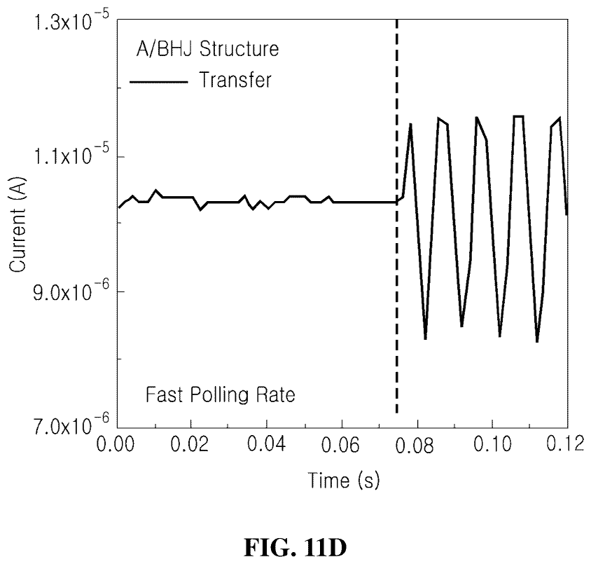

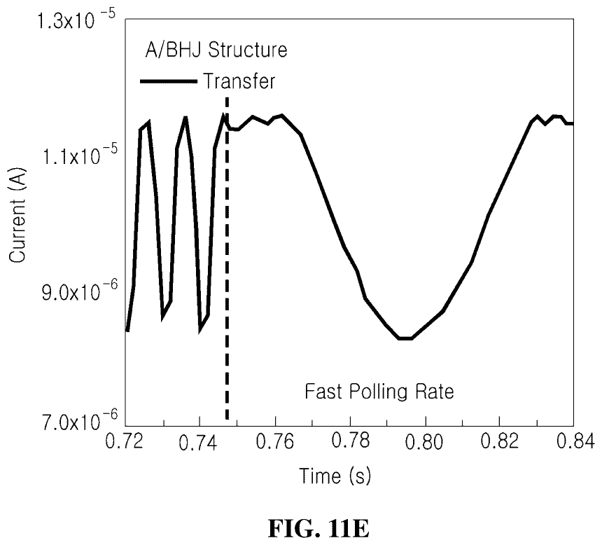

Taking advantage of the features of the OPD with the A/BHJ structure related to the high sensitivity and fast response obtained through the transfer printing, we designed a wireless data communication system based on optical pulses through digital-to-analog conversion as shown in FIG. 11A. When digital data is transmitted to the driver module, it is converted to analog data and then transmitted to the function generator for optical pulse generation.

The OPD with the A/BHJ structure minimized signal loss by capturing the FSK modulated pulse signal for precise data communication. Initially, a 10-digit signal of 1 010 101 010 was transmitted through the wireless data communication system (FIG. 11B).

When there was no signal, the photocurrent was maintained at the level of 0.010 A cm-2, and the OPD with the A/BHJ structure quickly detected the pulse signal as soon as it was applied to the transmitter (FIG. 11D). In addition, by introducing FSK modulation, the OPD with A/BHJ structure showed remarkable sensitivity to pulse signals when switching to lower frequencies in response to input data (FIG. 11E). Compared to Si PD, the OPD with A/BHJ structure showed improved sensitivity to the main signal while suppressing noise current.

Compared to other OPDs, the A/BHJ structure also improved the amplitude of the main signal, providing improved resolution that could distinguish even weak pulses. When another 10-digit signal of 0 101 101 001 was applied, the OPD with A/BHJ structure showed high sensitivity and fast response (FIG. 11C). Although low-frequency bands were used in the demonstration of wireless data communication systems, significant data transmission rates could be achieved using signals of several hundred kHz level, which achieved 160 Kbps data transmission, as shown in FIGS. 10C to 10F.

In conclusion, in order to improve the performance of a thin film type organic photodetector, a novel multilayer structure capable of effectively separating charges formed by an optical signal and suppressing reverse charge flow due to injected charges was introduced through a transfer printing process.

The electron acceptor thin film layer formed a stable interface through the transfer printing process suppressed dark current more than the existing structure by forming an effective injection barrier, and effectively separated the generated photocharges through excellent electron affinity, thereby inducing an improvement in the response signal.

In addition, it was confirmed that the data communication system including the photodetector according to the embodiment of the disclosure had excellent performance by showing a fast response speed and a wide bandwidth. In addition, it was proven that it can be used as a core technology for next-generation optical communication technology by showing a stable data transmission capability even in a bandwidth of 100 kHz or more.

The description of the disclosure is for illustrative purposes, and those skilled in the art will understand that it can be easily modified into other specific forms without changing the technical idea or essential features of the disclosure. Therefore, the embodiments described above should be understood as being exemplary in all respects and not limiting. For example, each component described as a single type may be implemented in a distributed manner, and likewise, components described as distributed may be implemented in a combined form.

The scope of the disclosure is indicated by the following claims, and all changes or modifications derived from the meaning and scope of the claims and their equivalent concepts should be interpreted as being included in the scope of the disclosure.

What is claimed is:

1. A photodetector comprising:
a first electrode;
a blocking layer disposed on the first electrode;
a photosensitive layer disposed on the blocking layer; and
a second electrode disposed on the photosensitive layer,
wherein the photosensitive layer comprises a bulk heterojunction layer in which a second electron acceptor material and a first electron donor material are mixed on a thin film layer comprising a first electron acceptor material.

2. The photodetector of claim 1, wherein the bulk heterojunction layer is defined through a transfer printing process.

3. The photodetector of claim 1, wherein the first electron acceptor material comprises one of ICBA (Indene-C60 bisadduct), PC₆₁BM([6,6]-Phenyl-C61-butyric acid methyl ester) and PC₇₁BM([6,6]-Phenyl-C71-butyric acid).

4. The photodetector of claim 1, wherein the first electron donor material is one of PM6, PBDTTTEFT, PCDTBT, and P3HT, and the second electron acceptor material is one of BTP-4F, BTP-4F-12, BTP-eC9, ITIC, IDTBR, and IEICO-4F.

5. The photodetector of claim 1, wherein the blocking layer is a hole blocking layer.

6. The photodetector of claim 1, wherein the blocking layer comprises ZnO.

7. The photodetector of claim 1, wherein the second electron acceptor material and the first electron donor material of the bulk heterojunction layer have a mass ratio range of 1:0.5 to 2.

8. A method for manufacturing a photodetector, the method comprising:
applying a blocking layer composition on a first electrode;
coating a thin film layer comprising a first electron acceptor material on the first electrode to which the blocking layer composition is applied;
forming a bulk heterojunction layer in which a second electron acceptor material and a first electron donor material are mixed through a transfer printing process on the thin film layer; and
forming a second electrode on the bulk heterojunction layer.

9. The method of claim 8, wherein the transfer printing process is performed at a speed range of 0.1 cm·s⁻¹ to 0.3 cm·s⁻¹.

10. The method of claim 8, wherein the forming of the bulk heterojunction layer is performed in a temperature range of 373K to 403K.

11. A photodetector comprising:
a first electrode;
a ZnO layer disposed on the first electrode;
a PC₇₁BM thin film layer disposed on the ZnO layer;
a mixed layer disposed on the PC₇₁BM thin film layer and comprising PM6 and BTP-4F-12; and
a second electrode disposed on the mixed layer.
